(19) United States
(12) Patent Application Publication
(10) Pub. No.: US 2008/0157778 A1
(43) Pub. Date: Jul. 3, 2008

(54) Estmation method, device, and electronic system utilizing the same

(75) Inventors: Yuh-Fwu Chou, Hsinchu County (TW); Po-Yin Tseng, Miaoli County (TW); Ming-Wang Cheng, Taoyuan County (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 12/000,989

(22) Filed: Dec. 19, 2007

(30) Foreign Application Priority Data
Dec. 29, 2006 (TW) 95149890

(51) Int. Cl. G01R 31/36

(52) U.S. Cl. 324/427; 702/63

(57) ABSTRACT

An estimation method for estimating a remaining capacity of a battery utilized by an electronic system is disclosed. The voltage of the battery is detected or is determined by a first reference value. When the duration of a specific state arrives at a preset time, a specific action is executed.

### BACKGROUND OF THE INVENTION

1. Field of the Invention

The invention relates to an estimation method, and more particularly to an estimation method for estimating remaining capacity of a battery.

2. Description of the Related Art

At present electronic devices tend to be thin, light and compact. Batteries are frequently utilized for driving electronic devices and are required in mobile electronic devices, such as mobile phones and electric cars. As the power stored in the battery is gradually depleted, abnormal phenomena, such as erratic movement or weal voice occur in the corresponding electronic device. Thus, a user determines the power of battery is inadequate. At this time, if the user does not immediately replace the battery, the electronic device is not capable of regular operation.

To ameliorate the described problems, the electronic device utilizes an estimation method to estimate remaining capacity of the battery and presents the estimated result on a panel display. Thus, the remaining capacity of the battery can be immediately determined. The accuracy of the conventional estimation method is, however, poor. If the electronic device utilizes the conventional estimation method, the remaining capacity of the battery cannot be correctly shown on the panel display of the electronic device. For example, although the power of the battery of a mobile phone is inadequate, an image presented on the panel display of the mobile phone indicates that the power of the battery is adequate. When the mobile phone is utilized to place a call, the mobile phone spontaneously shuts down. Thus, a user may not be able to determine the reason for the spontaneous shut down of the mobile phone.

### BRIEF SUMMARY OF THE INVENTION

An estimation method and device for estimating a remaining capacity of a battery utilized by an electronic system are provided. An exemplary embodiment of an estimation method is described in the following. Voltage of the battery is detected for determining a first reference value. When the duration of a specific state arrives at a preset time, a specific action is executed.

The estimation device estimates a remaining capacity of a battery utilized by an electronic system. The electronic system comprises a main device executing related functions and a display device displaying the remaining capacity of the battery. An exemplary embodiment of an estimation device comprises a voltage detection circuit and a processing circuit. The voltage detection circuit detects voltage of the battery. The processing circuit determines a first reference value according to -the detected result. The processing circuit executes a specific action when the duration of a specific state arrives at a preset time.

Electronic systems are also provided. An exemplary embodiment of an electronic system is capable of connecting to a power supply and comprises a main device, a battery, and an estimation device. The main device executes related functions. The battery stores a power provided by the power supply and provides a voltage to the main device. The estimation device estimates a remaining capacity of the battery and comprises a voltage detection circuit and a processing circuit. The voltage detection circuit detects voltage of the battery. The processing circuit determines a first reference value according to the detected result. The processing circuit executes a specific action when the duration of a specific state arrives at a preset time.

A detailed description is given in the following embodiments with reference to the accompanying drawings.

### BRIEF DESCRIPTION OF THE DRAWINGS

The invention can be more filly understood by referring to the following detailed description and examples with references made to the accompanying drawings, wherein:

FIG. 1a is a schematic diagram of an exemplary embodiment of an estimation method;

FIG. 1b is a state diagram of an exemplary embodiment of the estimation method;

FIG. 1c is a flowchart of an exemplary embodiment of the step S113 shown in FIG. 1a;

FIG. 1d is a schematic diagram of an exemplary embodiment of the electronic system;

FIG. 2a is a schematic diagram of an exemplary embodiment of the estimation device;

FIG. 2b is a schematic diagram of another exemplary embodiment of the estimation device;

FIG. 2c is a schematic diagram of an exemplary embodiment of a timing unit;

FIG. 3a is a schematic diagram of another exemplary embodiment of the electronic system;

FIG. 3b is a state diagram of another exemplary embodiment of the estimation method;

FIG. 3c is a flowchart of another exemplary embodiment of the step S113 shown in FIG. 1a;

FIG. 4a is a schematic diagram of another exemplary embodiment of the electronic system;

FIG. 4b is a state diagram of another exemplary embodiment of the estimation method;

FIG. 4c is a flowchart of another exemplary embodiment of the estimation method;

FIG. 5a is a state diagram of another exemplary embodiment of the estimation method;

FIG. 5b is a flowchart of another exemplary embodiment of the estimation method;

FIG. 6a is a state diagram of another exemplary embodiment of the estimation method;

FIG. 6b is a flowchart of another exemplary embodiment of the estimation method;

FIG. 7a is a state diagram of another exemplary embodiment of the estimation method;

FIG. 7b is a flowchart of another exemplary embodiment of the estimation method;

FIG. 7c is a flowchart diagram of another exemplary embodiment of the estimation method;

FIG. 8a is a state diagram of another exemplary embodiment of the estimation method; and

FIG. 8b is a flowchart of another exemplary embodiment of the estimation method.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

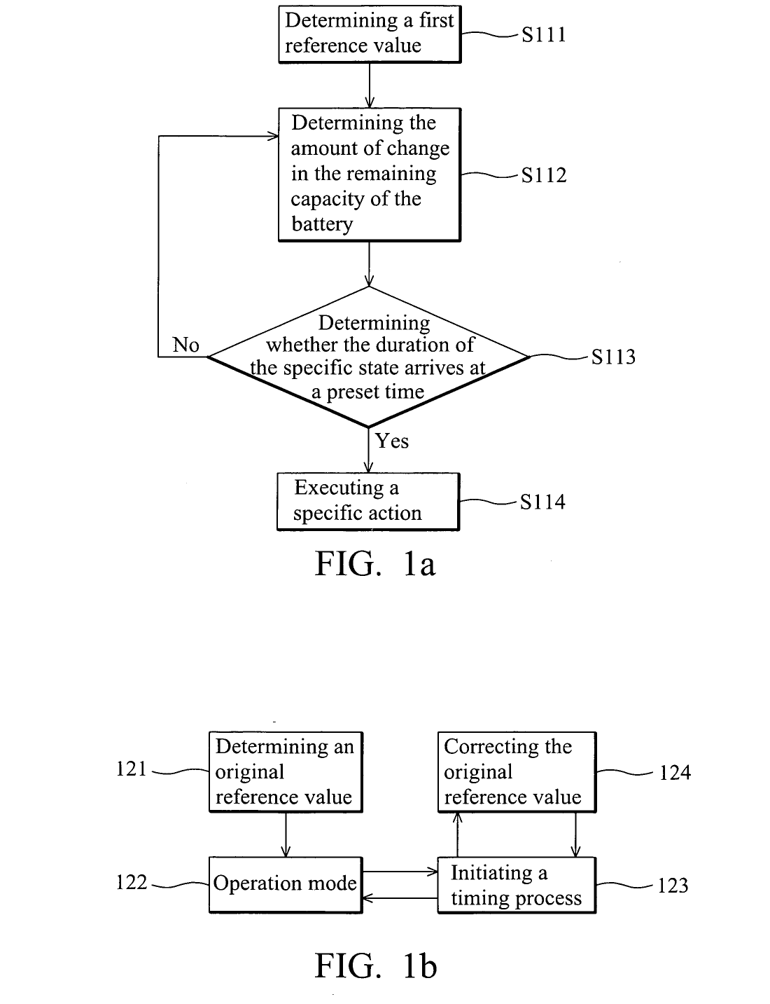

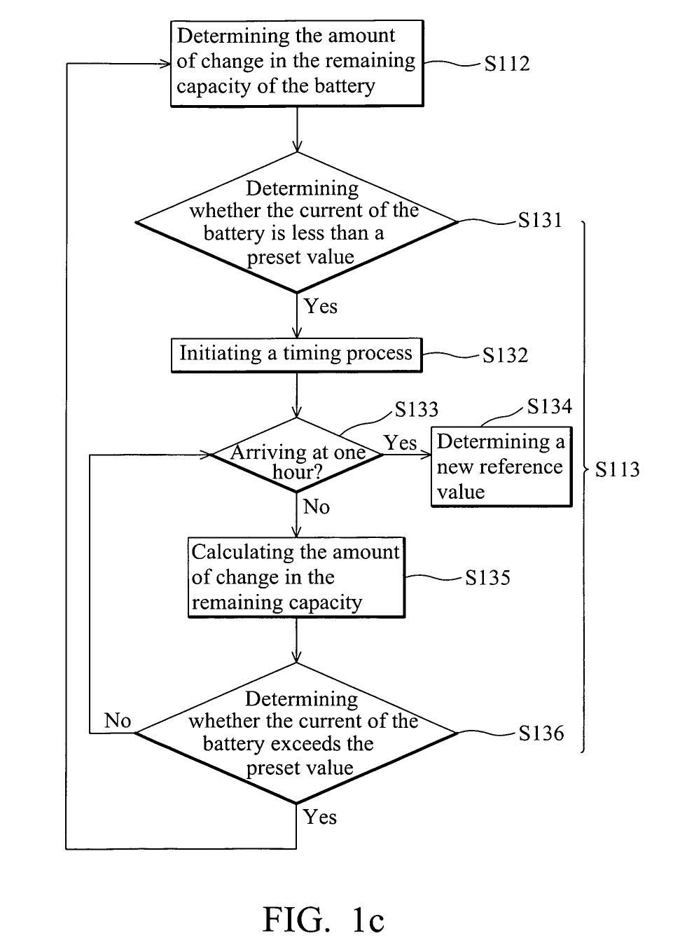

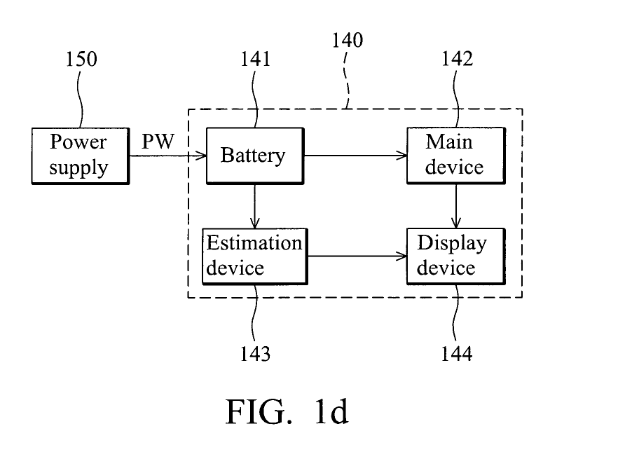

FIG. 1a is a schematic diagram of an exemplary embodiment of an estimation method. The estimation method estimates a remaining capacity of a battery utilized by an electronic system. First, the voltage of the battery is detected to determine a first reference value (step S111). In this embodiment, the voltage of the battery is compared with relational data to determine the first reference value. The relational data is a relationship between state of charge (SOC) of the battery and the voltage of the battery.

The amount of change in the remaining capacity of the battery is determined (step S112). A monitoring method is utilized to determine the amount of change in the remaining capacity of the battery. The first reference value is corrected according to the amount of change such that a second reference value is determined. In this embodiment, the monitoring method is calculating the amount of change according to an integration formula. Because the integral equation is well known to those skilled in the field, thus, description thereof is omitted.

Because the full charge capacity (FCC) of the battery affects the accuracy of the first reference value, the battery is discharged or one parameter is utilized for determining the FCC of the battery. The parameter is a usage state of the battery, an amount of time for using the battery, or a circulating amount of using the battery. The first reference value is corrected according to the FCC, thus, the accuracy of the first reference value is increased. A specific state is detected and determined whether the duration of the specific state has arrived at a preset time (step S113). A specific method is utilized for finding the specific state.

When the specific state does not occur or the duration of the specific state does not arrive to the preset time, amount of change in the remaining capacity of the battery is continuously determined (step S112). When the duration of the specific state arrives at the preset time, a specific action is executed (step S114).

The specific action is detecting the voltage of the battery again or turning off the electronic system. When the voltage of the battery is detected again, a second reference value is determined. The FCC of the battery is updated according to the first and the second reference and the amount of change in the remaining capacity of the battery.

The method for determining the second reference value is the same as that for determining the first reference value, thus, further description of the method for determining the second reference value is omitted. Additionally, the amount of charge of the battery or the amount of discharge of the battery divided by the amount of change in the remaining capacity of the battery equals the FCC of the battery.

If the electronic system is turned off, when the electronic system is turned on again, a new reference value is determined. When the voltage of the battery is detected again or the electronic system is turned on again, a new reference value is determined. The specific actions can eliminate an accumulative error of the amount of change in the remaining capacity.

FIG. 1b is a state diagram of an exemplary embodiment of the estimation method. State 121 is entered for determining an original reference value according to the voltage of the battery and state 122 is subsequently entered. In state 122, an operation mode is executed to wait for a specific state. In the operation mode, an integral equation processes the current of the battery for determining the amount of change in the remaining capacity of the battery.

When one specific state occurs, state 123 is entered for executing a timing process. During the timing process, if the specific state is not continuously maintained, the process returns to state 122 to again wait for a specific state. If the duration of the specific state arrives at a preset time, state 124 is entered for correcting the original reference value according to the voltage of the battery. When the original reference value is corrected, the state 123 is entered again for entering state 124 again such that a new reference value is determined according to the last reference value.

FIG. 1c is a flowchart of an exemplary embodiment of step S113 shown in FIG. 1a. In this embodiment, a specific method is utilized for detecting the current of the battery. First, it is determined whether the current of the battery is less than a preset value (step S131).

If the current of the battery is less than the preset value, a timing process is initiated because a specific state occurs (step S132). It is determined whether the duration of execution of the timing process arrives at one hour (step S133). If the duration of execution of the timing process arrives at one hour, a new reference value is determined according to the voltage of the battery (step S134). When the duration of execution of the timing process does not arrive at one hour, the amount of change in the remaining capacity is again calculated (step S135). In this embodiment, the description of step S135 is the same as that of step S112.

After calculating the amount of change in the remaining capacity, it is determined whether the current of the battery exceeds the preset value (step SI 36). If the current of the battery exceeds the preset value, the process returns to step S112. If the current of the battery is less than the preset value, the process returns to step S133.

FIG. 1d is a schematic diagram of an exemplary embodiment of the electronic system. Electronic system 140, such as an electric car or a mobile phone, is coupled to a power supply 150 for receiving a power PW and comprises a battery 141, a main device 142, an estimation device 143, and a display device 144.

Battery 141 stores the power PW provided by power supply 150 and provides a voltage to main unit 142. Power supply 150 is a charger for charging battery 141. Main device 142 executes related functions. The executed related functions correspond to the kind of main device 142. Thus, the kinds of executed related functions are not limited. For example, if electronic system 140 is a mobile phone, main device 142 executes communication related functions. If electronic system 140 is an electric car, main device 142 executes vehicle related functions. Estimation device 143 estimates the remaining capacity of battery 141 and provides the estimated result to display device 144. Display device 144 is controlled by main device 142 to display a quantity corresponding to the estimated result.

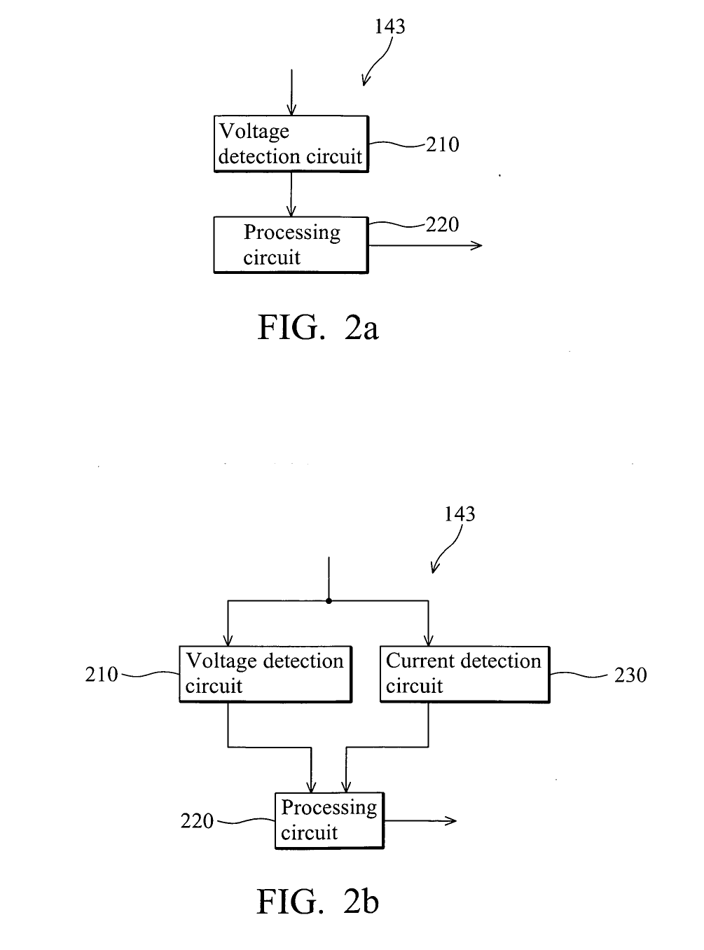

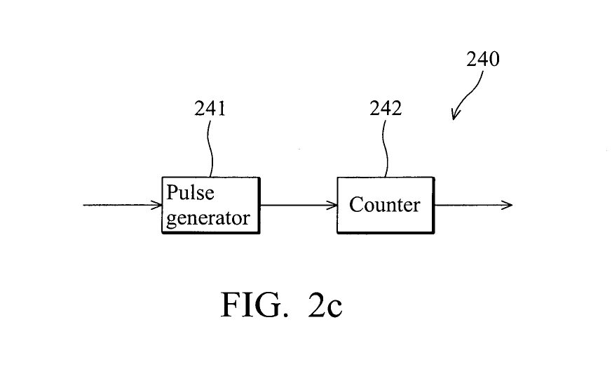

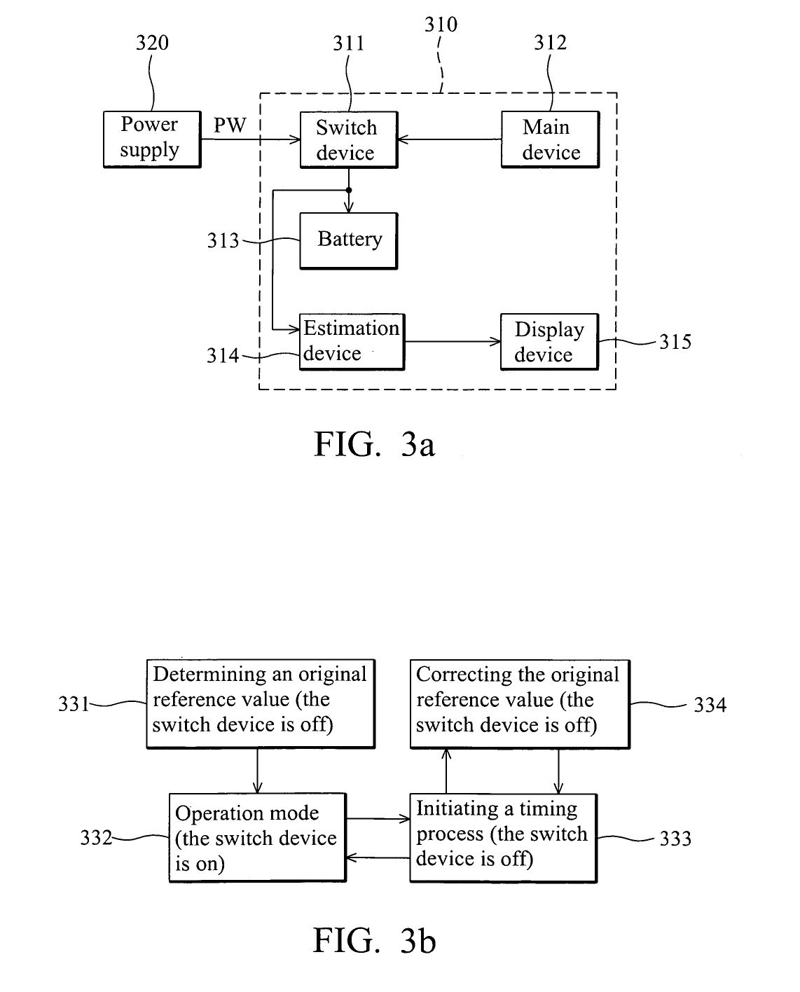

FIG. 2a is a schematic diagram of an exemplary embodiment of the estimation device. Estimation device 143 comprises a voltage detection circuit 210 and a processing circuit 220. Voltage detection circuit 210 detects the voltage of battery 141. Processing circuit 220 determines a first reference value according to the detected result provided by voltage detection circuit 210. In this embodiment, processing circuit 220 compares the detected result and relational data for determining the first reference value. The relational data is a relationship between state of charge (SOC) of battery 141 and the voltage of the battery 141.

After the first reference value is determined, if the duration of a specific state arrives at a preset time, processing circuit 220 executes a specific action. The specific action taken according to the detected result determines a second reference value, corrects the first reference value, or directly turns off electronic system 140. In this embodiment, the reference value (the first or the second reference value) determined by processing circuit 220 indicates the remaining capacity of battery 141. Thus, the quantity displayed in display device 144 corresponds to the remaining capacity of battery 141.

If the specific action is taken in response to the detected result is to determine a second reference value, the FCC of battery 141 is updated according to the first and the second reference values. The method for determining the second reference value is the same as that for determining the first reference value.

In some embodiments, processing circuit utilizes a monitoring method to determine the amount of change in the remaining capacity. When the duration of the specific state arrives at the preset time, processing circuit 220 corrects the first reference value according to the amount of change such that a new reference value is determined.

FIG. 2b is a schematic diagram of another exemplary embodiment of the estimation device. FIG. 2b is similar to FIG. 2a except for the addition of a current detection unit 230. Current detection unit 230 detects the current of battery 141. Processing circuit 220 utilizes an integration formula to process the detected result provided by current detection unit 230 Processing circuit 220 determines the FCC of battery 141 according to the first and the second reference values and the integration result.

Processing circuit 220 corrects the first reference value according to the FCC of battery 141 such that the accuracy of the first reference value is increased. In some embodiments, processing circuit 220 determines the FCC of battery 141 according to the usage state of battery 141, the amount of time for using battery 141, or the circulating amount of using battery 141.

Processing circuit 220 utilizes a specific method to determine whether the specific state occurs. In this embodiment, the specific method is detecting the current of battery 141. When the current of battery 141 is less than a preset value, the specific state occurs. If the duration of the specific state arrives at a preset time, such as one hour, processing circuit 220 executes a specific action.

In some embodiments, processing circuit 220 further comprises a timing unit (not shown) for calculating the duration of the specific state. FIG. 2c is a schematic diagram of an exemplary embodiment of a timing unit. Timing unit 240 comprises a pulse generator 241 and a counter 242.

When the specific state occurs, processing circuit 220 triggers pulse generator 241, thus, an immobilizing frequency is generated. Counter 242 calculates the pulse amount of the immobilizing frequency for determining whether the duration of the specific state arrives at a preset time. If the duration of the specific state arrives at the preset time, counter 242 generates a reply signal to processing circuit 220. Thus, a specific action is executed by processing circuit 220. In some embodiments, a timing unit is composed of a capacitor and a resistor. The capacitor stores charge. The resistor controls charging and/or discharging rate of the capacitor.

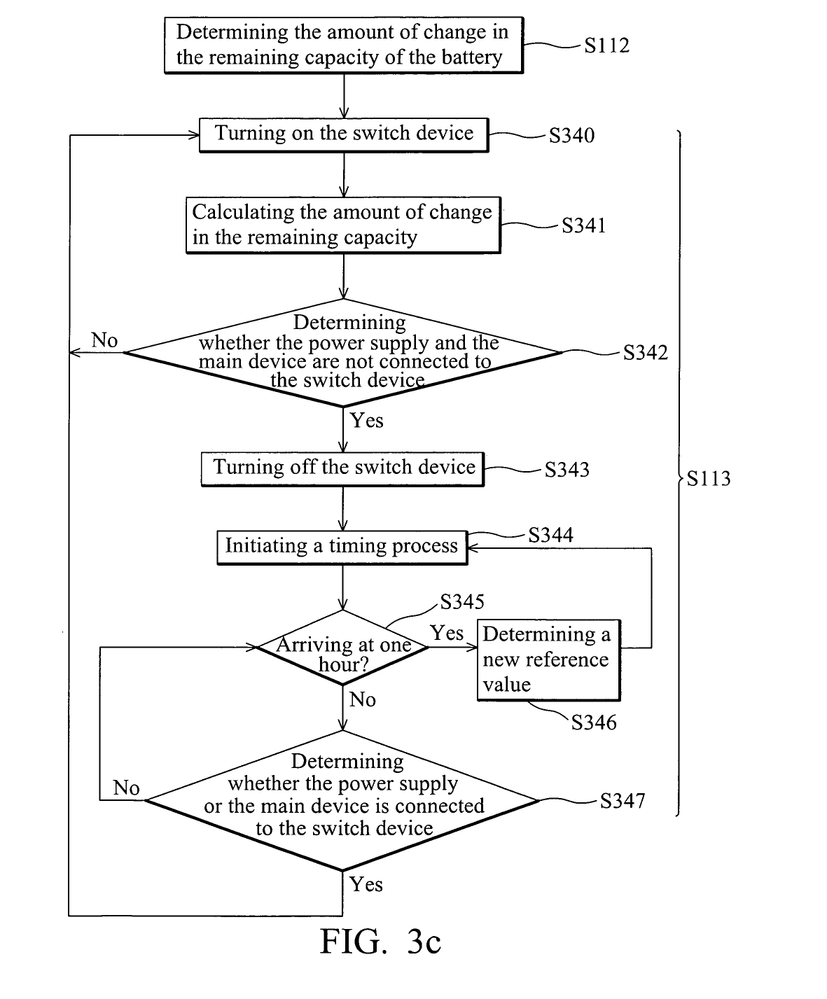

FIG. 3a is a schematic diagram of another exemplary embodiment of the electronic system. FIG. 3a is similar to FIG. 1d except for the addition of a switch device 311. Switch device 311 transmits the power PW provided by power supply 320 to battery 313 or utilizes battery 313 to drive a load, such as main device 312.

Estimation device 314 determines a reference value according to the voltage of battery 313. When the duration of a specific state arrives at a preset time, a specific action is executed. In this embodiment, estimation device 314 determines whether to execute the specific action according to a connection relationship of switch device 311.

When power supply 320 or main device 312 is connected to switch device 311, estimation device 314 does not execute the specific action. When power supply 320 and main device 312 are not connected to switch device 311, estimation device 314 are ready to executes the specific action. The method for determining the reference value and the executed specific action are respectively the same as that for determining the first reference value and the specific action described in above.

FIG. 3b is a state diagram of another exemplary embodiment of the estimation method. FIG. 3b is similar to FIG. 1b with the exception that the switch device 311 is turned on in state 332 and the switch device 331 is turned off in states 331, 333, and 334. Because states 331-334 are respectively the same as states 121-124 shown in FIG. 1b, descriptions of states 331-334 are omitted for brevity.

FIG. 3c is a flowchart of another exemplary embodiment of the step S113 shown in FIG. 1a. With reference to FIG. 3a, after step 112, switch device 311 is turned on (step S340). The amount of change in the remaining capacity is calculated (step S341). Then, it is determined whether power supply 320 and main device 312 are not connected to switch device 311 (step S342).

When power supply 320 and main device 312 are not connected to switch device 311, it is the condition that a specific state occurs. Thus, switch device 311 is turned off (step S343) and a timing process is then initiated (step S344). It is determined whether the duration of execution of the timing process arrives at one hour (step S345). If the duration of execution of the timing process arrives at one hour, a new reference value is determined according to the voltage of battery 313 (step S346) and the process then returns to step S344. When the duration of execution of the timing process does not arrive at one hour, it is determined whether power supply 320 or main device 312 is connected to switch device 311 (step S347). If neither the power supply 320 nor the main device 312 is connected to switch device 311, the process returns to step S345. If power supply 320 or main device 312 is connected to switch device 311, the process returns to step S340.

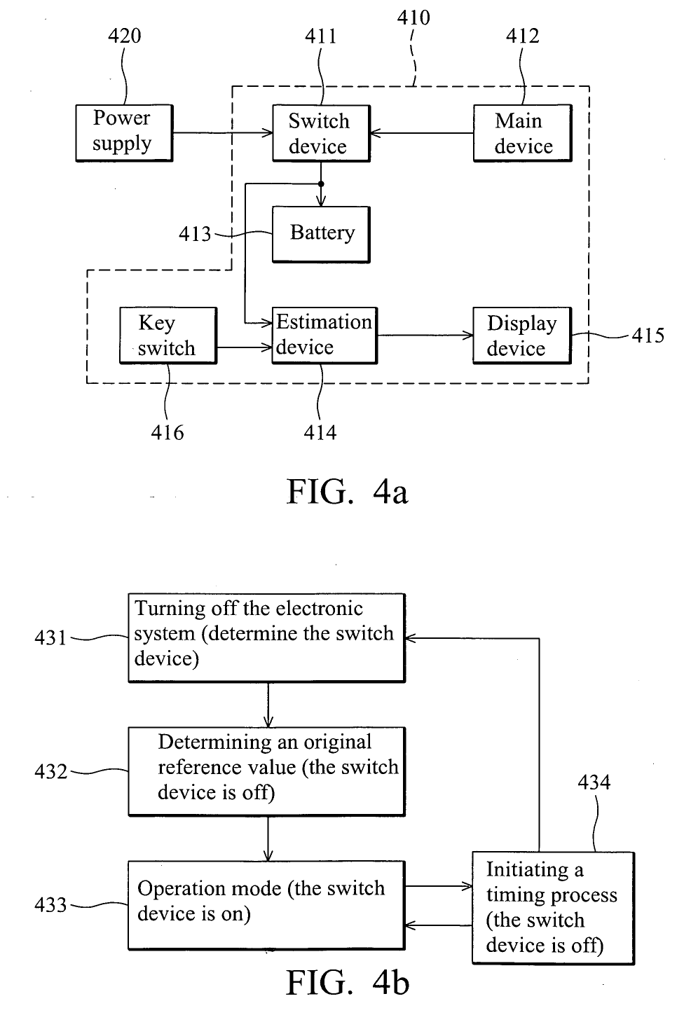

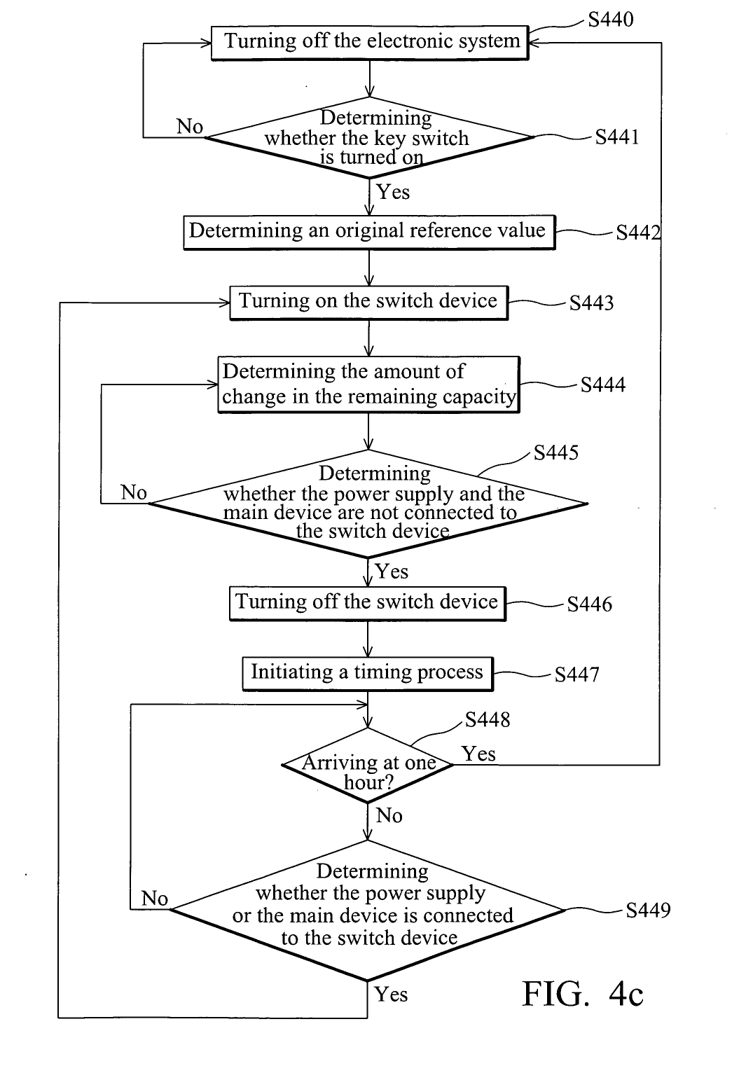

FIG. 4a is a schematic diagram of another exemplary embodiment of the electronic system. FIG. 4a is similar to FIG. 3a except for the addition of a key switch 416. Key switch 416 determines whether to turn on electronic system 410. The operations of power supplies 320 and 420 are the same. The operations of switch devices 311 and 411 are the same. The operations of main devices 312 and 412 are the same. The operations of batteries 313 and 413 are the same. The operations of display devices 315 and 415 are the same. Thus, descriptions of power supply 420, switch device 411, main device 412, battery 413, and display device 415 are omitted for brevity.

When key switch 416 is turned on, estimation device 414 determines a reference value according to the voltage of battery 413. When the duration of a specific state arrives at a preset time, a specific action is executed. In this embodiment, the specific state is same as the descriptions of FIG. 3a. In other words, the specific state is determined when power supply 420 and main device 412 are not connected to switch device 411. In this embodiment, the specific action is turning off electronic system 410.

FIG. 4b is a state diagram of another exemplary embodiment of the estimation method. In state 431, it is determined whether the key switch is turned on. When key switch 416 is turned on, state 432 is entered for determining an original reference value according to the voltage of battery 413 and turning off switch device 411. Then, state 433 is entered for entering an operation mode, turning on switch device 411, and awaiting a specific state. In the operation mode, an integration formula is utilized to process the current of battery 413. Thus, the amount of change in the remaining capacity is determined in state 433.

When the specific state occurs, state 434 is entered. Thus, switch device 411 is turned off to disconnect the power supply and the main device, and a timing process is initiated. In the timing process, if the specific state is not continuously maintained, state 433 is entered again for continuously awaiting a specific state. If the duration of the specific state arrives at a preset time, state 431 is entered for turning off electronic system 410. In this embodiment, a specific state is entered when power supply 420 and main device 412 are disconnected to the battery 413 by turning off the switch device 411.

FIG. 4c is a flowchart of another exemplary embodiment of the estimation method. With reference to FIG. 4a, electronic system 410 is turned off (step S440). Then, it is determined whether key switch 411 is turned on (step S411). If key switch 411 is turned on, the voltage of battery 413 is detected for determining an original reference value (step S442). If key switch 411 is turned off, the process returns to step S440.

When the original reference value is determined, switch device 411 is turned on (step S443). Then, the amount of change in the remaining capacity of battery 413 is determined (step S444). It is determined whether a specific state occurs. In other words, it is determined whether both the power supply 420 and the main device 412 are disconnected to switch device 411 (step S445). When power supply 420 or main device 412 is connected to switch device 411, the process returns to step S444. If both the power supply 420 and the main device 412 are disconnected to switch device 411, switch device 411 is turned off (step S446) and then a timing process is initiated (step S447).

It is determined whether the duration of execution of the timing process arrives at one hour (step S448). If the execution of the timing process arrives at the duration of one hour, the process returns to step S440. Before the execution of the timing process arrives at the duration of one hour, it is continuously checked whether power supply 420 or main device 412 is connected to switch device 411 (step S449). When power supply 420 or main device 412 is connected to switch device 411, the process returns to step S443. If power supply 420 and main device 412 are not connected to switch device 411, the process returns to step S448.

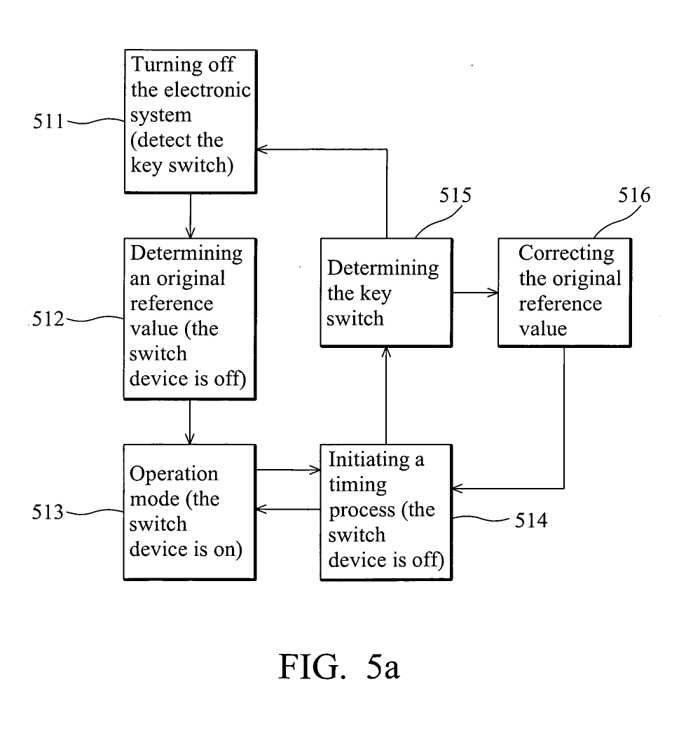

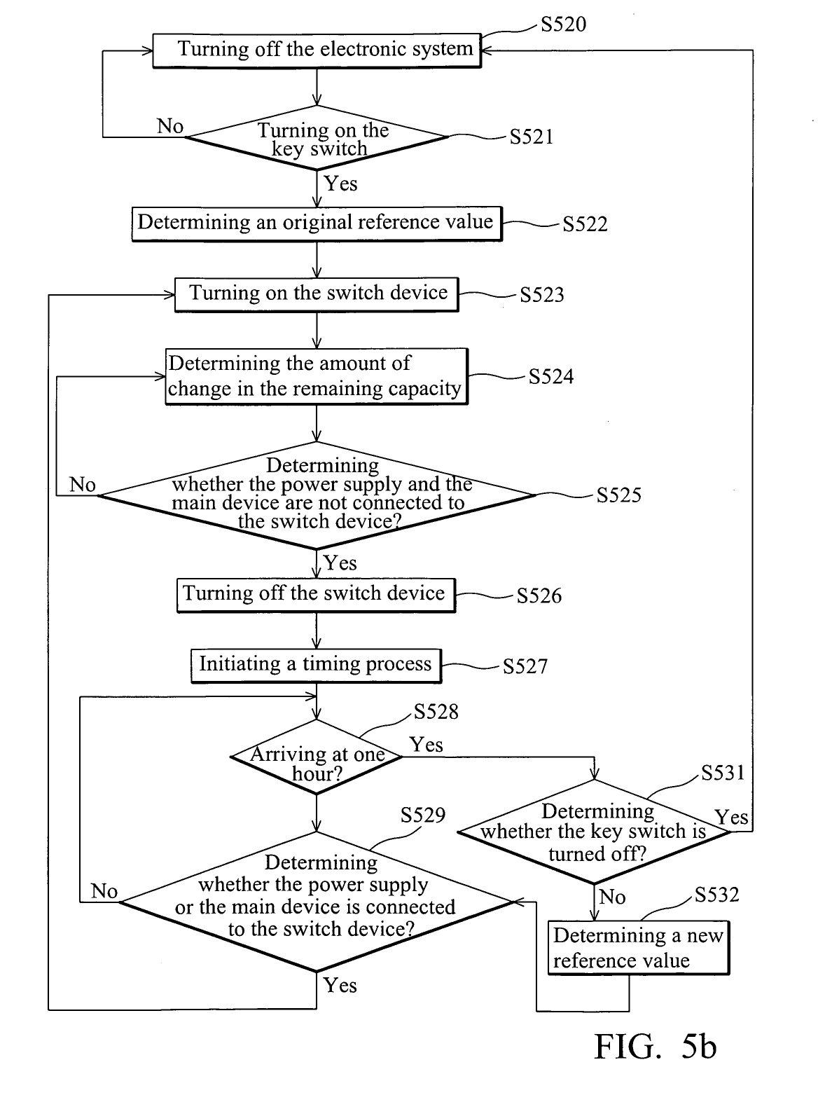

FIG. 5a is a state diagram of another exemplary embodiment of the estimation method. FIG. 5a is similar to FIG. 4b except for the addition of states 515 and 516. Because states 511-514 are respectively the same as states 431-434 shown as FIG. 4b, descriptions of states 511-514 are omitted for brevity.

If the duration of execution of the timing process arrives at a preset time, state 515 is entered for determining whether key switch 411 is turned on. When key switch 411 is turned off, state 511 is entered for turning off the electronic system. When key switch 411 is turned on, state 516 is entered for correcting the original reference value. When the original reference value is corrected, state 514 is entered again for initiating the timing process. Thus, the reference value is again corrected for determining a new reference when states 515 and 516 are entered again.

FIG. 5b is a flowchart of another exemplary embodiment of the estimation method. FIG. 5b is similar to FIG. 4c except for the addition of steps S531 and S532. Because steps S520-S529 are respectively the same as steps S440-S449 shown as FIG. 4c, descriptions of steps S520-S529 are omitted.

With reference to FIG. 4A, when the duration of execution of the timing process arrives at one hour, it is determined whether key switch 411 is turned off (step S531). If key switch 411 is turned on, a new reference value is determined according to the voltage of battery 413 (step S532) and then the process returns to step S529. If key switch 411 is turned off, the process returns to step S520.

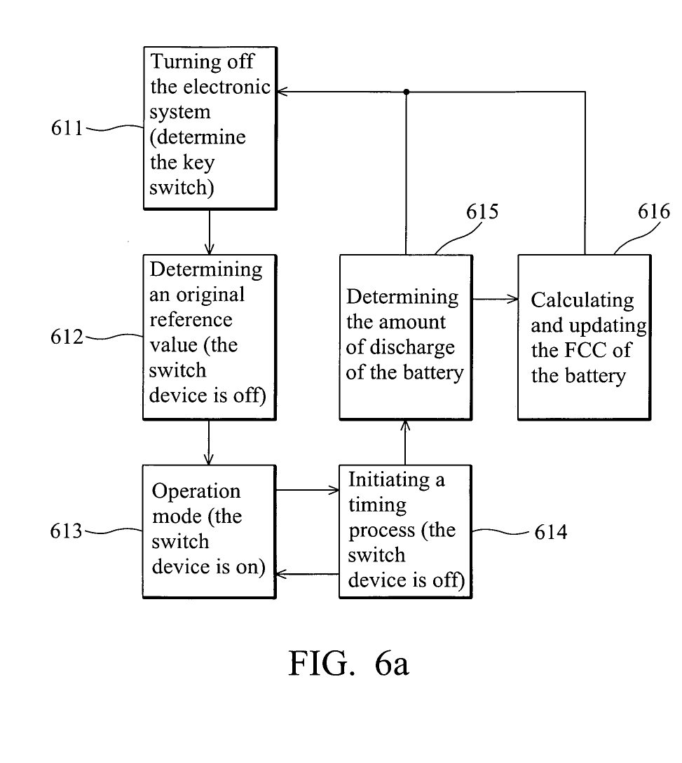

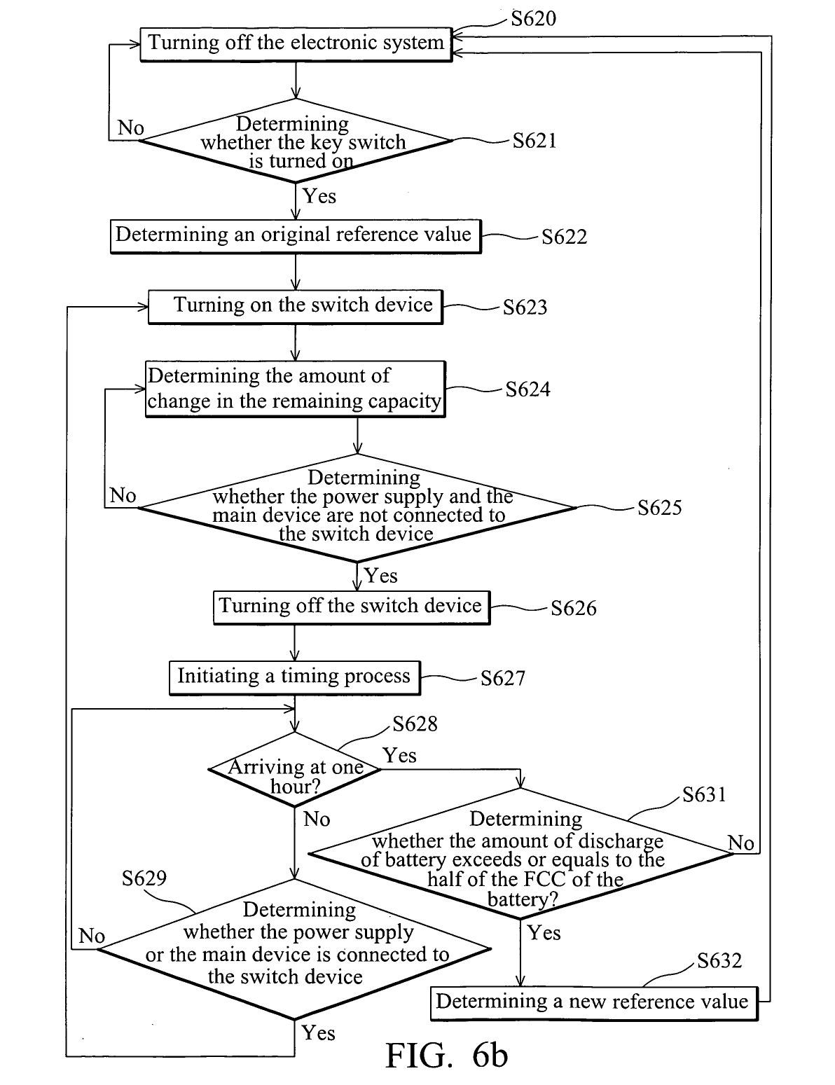

FIG. 6a is a state diagram of another exemplary embodiment of the estimation method. FIG. 6a is similar to FIG. 4b except for the addition of states 615 and 616. Because the state 611-614 are respectively the same as the states 431-434, descriptions of states 611-614 are omitted.

If the duration of execution of the timing process arrives at a preset time, the state 615 is entered to determine the amount of discharge of the battery. When the amount of discharge exceeds or equals half of the FCC of the battery, state 616 is entered for calculating and updating the FCC of the battery.

During the discharge process, the battery cannot be charged. If a charge action is executed, the amount of discharge of the battery is determined again. If the discharge amount is less than the half of the FCC of the battery or the FCC of the battery is updated, the state 611 is entered for turning off the electronic system.

FIG. 6b is a flowchart of another exemplary embodiment of the estimation method. FIG. 6b is similar to FIG. 4c except for the addition of steps S631 and S632. The steps S620-S629 are respectively the same as the steps S440-S449, descriptions of steps S620-S629 are omitted.

With reference to FIG. 4a, when the duration of execution of the timing process arrives at one hour, it is determined whether the amount of discharge of the battery exceeds or equals half of the FCC of the battery (step S631). If the amount of discharge of the battery exceeds or equals half of the FCC of the battery, a new reference value is determined according to the voltage of the battery (step S632) and the process then returns to step S620. If the amount of discharge of the battery is less than the half of the FCC of the battery, the process returns to step S620.

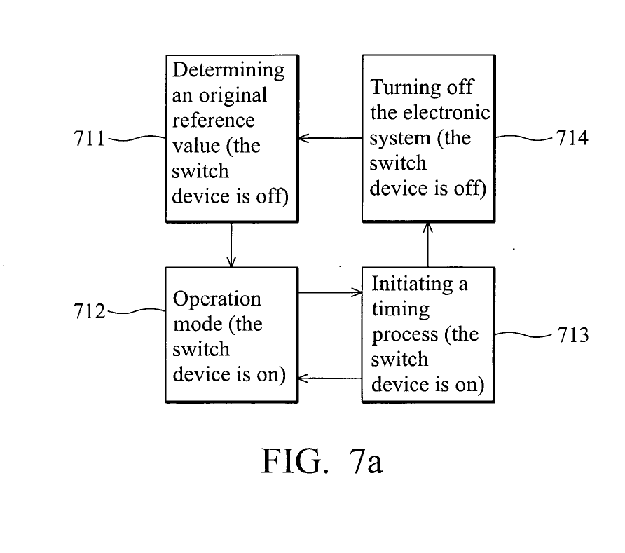

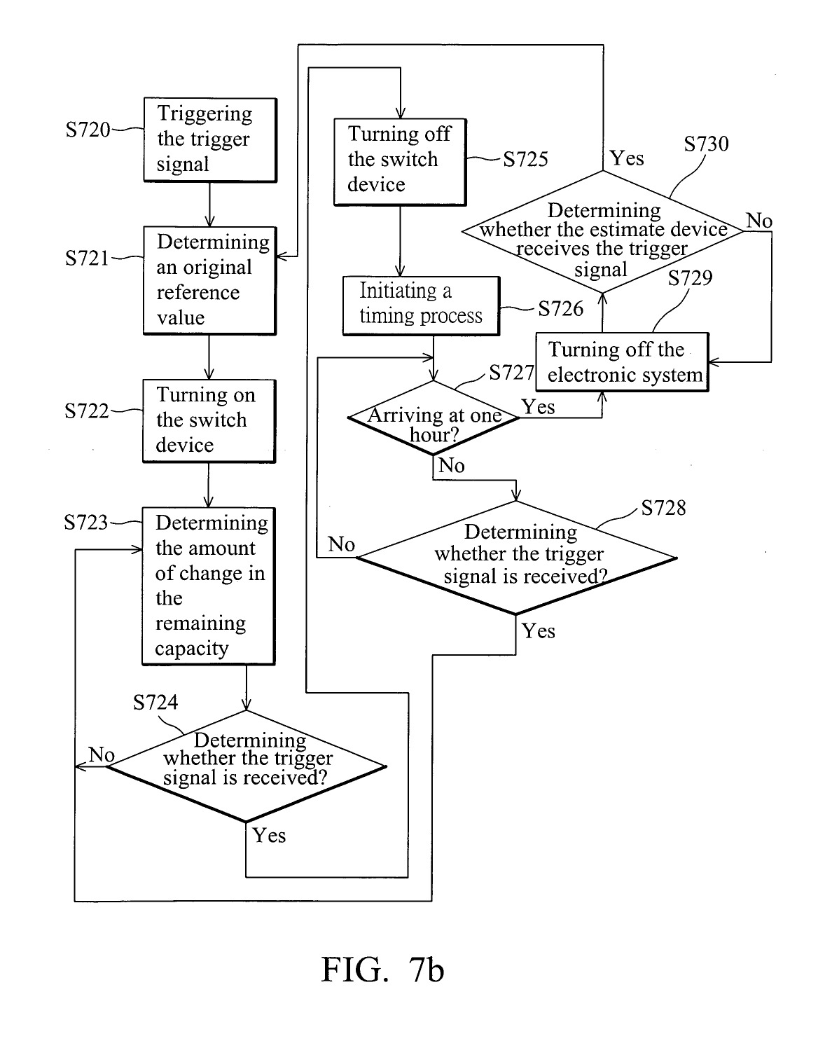

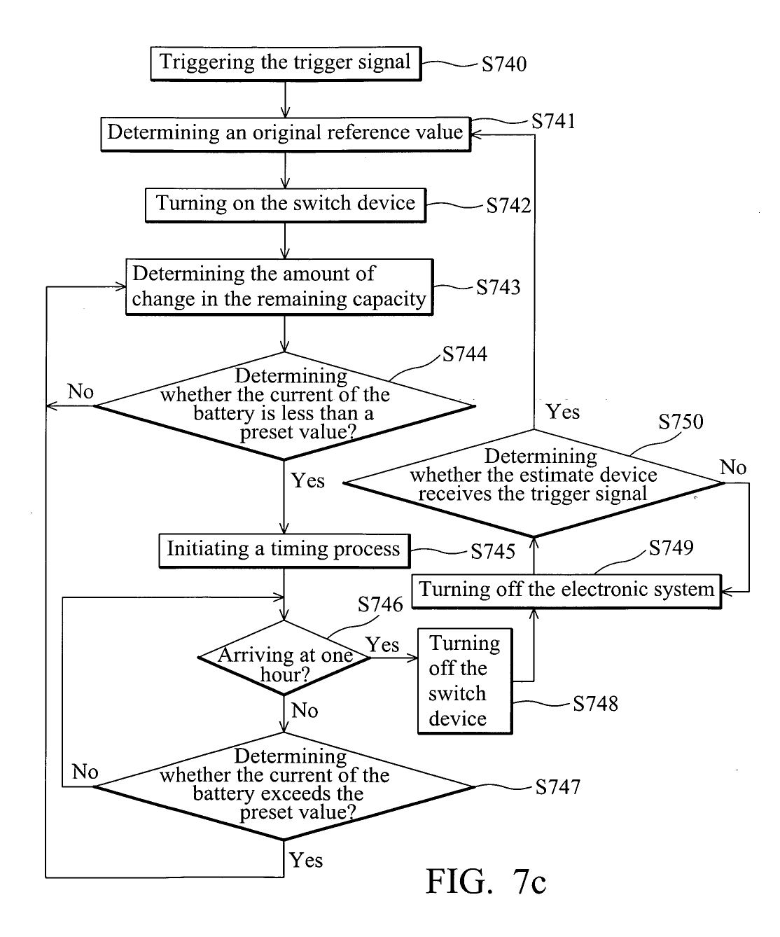

FIG. 7a is a state diagram of another exemplary embodiment of the estimation method. With reference to FIG. 3a, state 711 is entered for determining an original reference value according to the voltage of battery 313. State 712 is entered for entering an operation mode and turning on switch device 311. If a trigger signal (not shown) is triggered, state 713 is entered for initiating a timing process.

In the timing process, if the duration of execution of the timing process arrives at a preset time, state 714 is entered for turning off the electronic system. After turning off the electronic system, if estimation device 314 receives the trigger signal, state 711 is entered for determining a new reference value according to the voltage of the battery. Additionally, in the timing process, if the trigger signal is received again before the preset time arrives, state 712 is entered for entering the operation mode again and interrupting the timing process.

In some embodiments, in the operation mode, it is determined whether the current of battery 313 is less than a preset value. If the current of battery 313 is less than a preset value, state 713 is entered for executing the timing process. During executing the timing process, if the current of battery 313 exceeds the preset value, state 712 is entered again. If the duration of execution of the timing process arrives at a preset time, switch device 311 and the electronic system are turned off.

FIG. 7b is a flowchart of another exemplary embodiment of the estimation method. With reference to FIG. 3a, the trigger signal is triggered (step S720). An original reference value is determined according to the voltage of the battery 313 (step S721). Then switch device 311 is turned on (step S722).

The amount of change in the remaining capacity of battery 313 is determined (step S723). It is determined whether a specific state occurs, in other words whether the trigger signal is received (step S724). If the trigger signal is not received, the process returns to step S723. If the trigger signal is received, switch device is turned off (step S725) and then a timing process is initiated (step S726).

It is determined whether the duration of execution of the timing process arrives at one hour (step S727). If the duration of execution of the timing process arrives at one hour, the electronic system is turned off (step S729) and then it is determined whether estimation device 314 receives the trigger signal. If estimation device 314 does not receive the trigger signal, the process returns to step S729. If estimation device 314 receives the trigger signal, the process returns to step S721.

If the duration of execution of the timing process is less than one hour, it is determined whether the trigger signal is received again (step S728). If the trigger signal is received again, the process returns to step S723. If trigger signal is not. received again, the process returns to step S727.

FIG. 7c is a flowchart diagram of another exemplary embodiment of the estimation method. FIG. 7c is similar to FIG. 7b with the exception that steps 744 and 747 are respectively different from steps S724 and S728. Because the other steps S740-S743, S745, S746, and S748-S750 are respectively the same as steps S720-S723, S725-S727, S729, and S730, the steps S740-S743, S745, S746, and S748-S750 are omitted. Shown as FIG. 7c, it is determined whether the current of the battery is less than a preset value (step S744). If the current of the battery is less than the preset value, a timing process is initiated (step S745). If the duration of execution of the timing process arrives at one hour, the switch device is turned off (step S748) and then the electronic system is turned off (step S749). Additionally, it is determined whether the current of the battery exceeds the preset value (step S747). If the current of the battery exceeds the preset value, the process returns to step S743. If the current of the battery is less than the preset value step the process returns to S746.

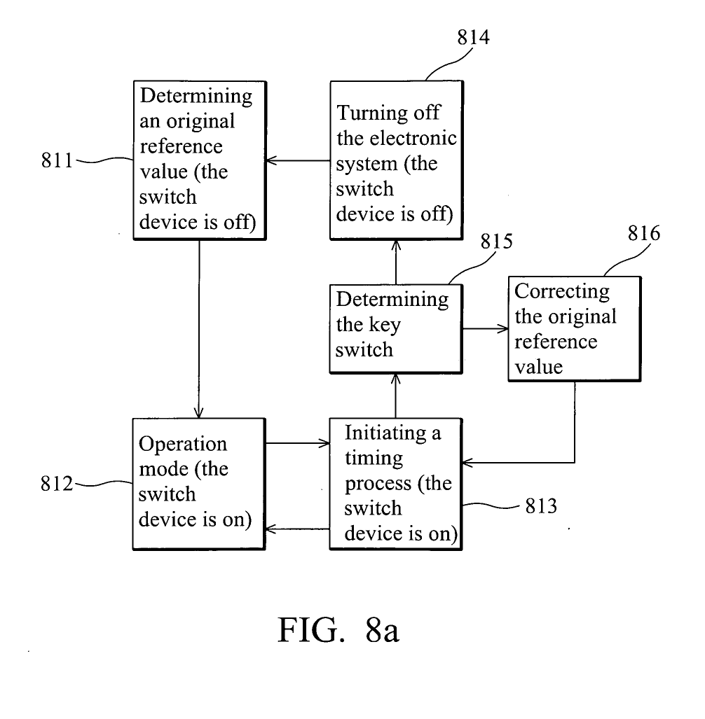

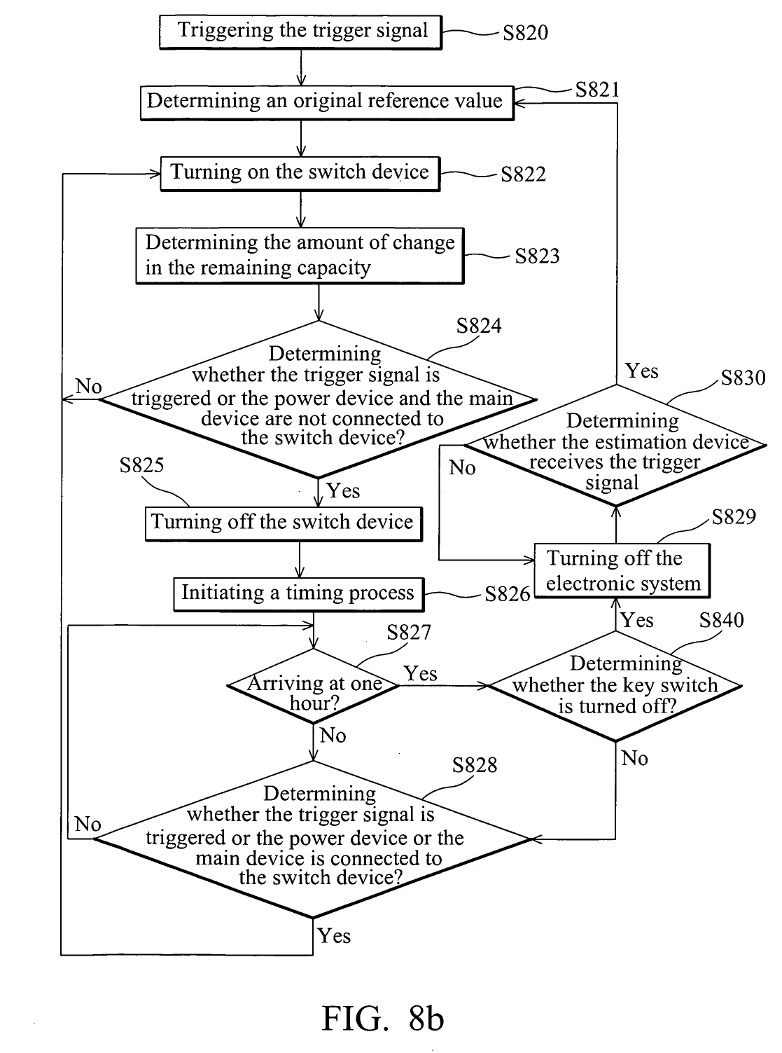

FIG. 8a is a state diagram of another exemplary embodiment of the estimation method. Because state 811-814 are respectively the same as states 711-714 shown in FIG. 7a, descriptions of states 811-814 are omitted. Because state 815 and 816 are respectively the same as states 515 and 516 shown in FIG. 5a, descriptions of states 815 and 816 are omitted.

In some embodiments, in the operation mode, if the trigger signal is triggered or the power supply and the main device are not connected to the switch device, the switch device is turned off and a timing process is initiated. During the timing process, if the trigger signal is triggered or the power supply or the main device is connected to the switch device, the switch device is turned on and the operation mode resumes.

FIG. 8b is a flowchart of another exemplary embodiment of the estimation method. FIG. 8b is similar to FIG. 7b with the exception steps S824 and S840. Because steps S820-S823, S825-S827, S829, and S830 are respectively the same as steps S720-S723, S725-S727, S729, and S730 shown in FIG. 7b, descriptions of steps S820-S833, S825-S827, S829, and S830 are omitted.

With reference to FIG. 4a, it is determined whether the trigger signal is triggered or both power supply 420 and main device 712 are disconnected to switch device 411 (step S824). If the trigger signal is triggered or both power supply 420 and main device 712 are not connected to switch device 411, the switch device is turned off (step S825). If the trigger signal is not triggered, and either power supply 420 or main device 712 is connected to switch device 411, the process returns to step S823.

It is determined whether the trigger signal is triggered or power supply 420 or main device 712 is connected to switch device 411 (step S828). If the trigger signal is triggered or power supply 420 or main device 712 is connected to switch device 411, step S822 is executed. If the trigger signal is not triggered and both power supply 420 and main device 712 are disconnected to switch device 411, step S827 is executed.

It is determined whether key switch 416 is turned off (step S840). If key switch 416 is turned off, the electronic system is turned off (step S829). If key switch 416 is turning on, the process returns to step 828.

In the estimation method, device, or the electronic system, when the duration of a specific state arrives at a preset value, a specific action is executed. The invention is not limited to the described specific state and the specific action.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An estimation method for estimating a remaining capacity of a battery utilized by an electronic system, comprising:
detecting voltage of the battery for determining a first reference value; and
executing a specific action when the duration of a specific state arrives at a preset time.

2. The estimation method as claimed in claim 1, wherein the specific action is again detecting the voltage of the battery for determining a second reference value.

3. The estimation method as claimed in claim 2, further comprising:
updating a full charge capacity (FCC) of the battery according to the first and the second reference values.

4. The estimation method as claimed in claim 2, further comprising:
providing relational data; and
comparing the voltage of the battery and the relational data for determining the first or the second reference value.

5. The estimation method as claimed in claim 4, wherein the relational data is a relationship between state of charge (SOC) of the battery and the voltage of the battery.

6. The estimation method as claimed in claim 1, further comprising:
utilizing a monitoring method to determine an amount of change in the remaining capacity; and
correcting the first reference value according to the amount of change such that a second reference value is determined.

7. The estimation method as claimed in claim 6, wherein the monitoring method is calculating the amount of change according to an integration formula.

8. The estimation method as claimed in claim 7, further comprising:
determining a full charge capacity (FCC) of the battery; and
correcting the first reference value according to the FCC.

9. The estimation method as claimed in claim 8, wherein the FCC is determined when the battery is discharged.

10. The estimation method as claimed in claim 1, further comprising:
utilizing a specific method to find the specific state.

11. The estimation method as claimed in claim 10, wherein the specific method is detecting current of the battery.

12. The estimation method as claimed in claim 1, further comprising:
providing relational data; and
comparing the voltage of the battery and the relational data for determining the first reference value.

13. The estimation method as claimed in claim 12, wherein the relational data is a relationship between state of charge (SOC) of the battery and the voltage of the battery.

14. The estimation method as claimed in claim 1, wherein-the specific state is found when current of the battery is less than a preset value.

15. The estimation method as claimed in claim 1, further comprising:
according to a usage state of the battery to determine a full charge capacity (FCC) of the battery.

16. The estimation method as claimed in claim 1, further comprising:
according to an amount of time for using the battery to determine a full charge capacity (FCC) of the battery.

17. The estimation method as claimed in claim 1, further comprising:
according to a circulating amount of using the battery to determine a full charge capacity (FCC) of the battery.

18. The estimation method as claimed in claim 1, wherein the specific action is turning off the electronic system.

19. An estimation device for estimating a remaining capacity of a battery utilized by an electronic system comprising a main device executing related functions and a display device displaying the remaining capacity of the battery, comprising:
a voltage detection circuit detecting voltage of the battery; and
a processing circuit determining a first reference value according to the detected result, wherein the processing circuit executes a specific action when the duration of a specific state arrives at a preset time.

20. The estimation device as claimed in claim 19, wherein the specific action is again detecting the voltage of the battery to determine a second reference value.

21. The estimation device as claimed in claim 20, wherein the display device is changed to display the remaining capacity corresponding to the second reference value.

22. The estimation device as claimed in claim 20, wherein the processing circuit updates full charge capacity of the battery according to the first and the second reference values.

23. The estimation device as claimed in claim 20, wherein the processing circuit compares the voltage of the battery and relational data for determining the first or the second reference value.

24. The estimation device as claimed in claim 23, wherein the relational data is a relationship between state of charge (SOC) of the battery and the voltage of the battery.

25. The estimation device as claimed in claim 19, wherein the processing circuit determines an amount of change in the remaining capacity according to a monitoring method and corrects the first reference value according to the amount of change for determining a second reference value.

26. The estimation device as claimed in claim 25, wherein the processing circuit further comprises a current detection unit to detect current of the battery.

27. The estimation device as claimed in claim 26, wherein the processing circuit utilizes an integration formula to process the current of the battery.

28. The estimation device as claimed in claim 27, wherein the processing circuit determines a full charge capacity of the battery according to the first and the second reference values and the integral result.

29. The estimation device as claimed in claim 28, wherein the processing circuit corrects the first reference value according to the full charge capacity.

30. The estimation device as claimed in claim 27, wherein the processing circuit corrects the first reference value to determine a second reference value according to the integral result.

31. The estimation device as claimed in claim 19, wherein the processing circuit finds the specific state according to a specific method.

32. The estimation device as claimed in claim 31, wherein the specific method is detecting current of the battery.

33. The estimation device as claimed in claim 19, wherein the specific state is found when current of the battery is less than a preset value.

34. The estimation device as claimed in claim 19, wherein the processing circuit determines a full charge capacity of the battery according to a usage state of the battery.

35. The estimation device as claimed in claim 19, wherein the processing circuit determines a full charge capacity of the battery according to an amount of time for using the battery.

36. The estimation device as claimed in claim 19, wherein the processing circuit determines a full charge capacity of the battery according to a circulating amount of using the battery.

37. The estimation device as claimed in claim 19, wherein the display device displays the remaining capacity corresponding to the first reference value when the first reference value is determined by the processing circuit.

38. The estimation device as claimed in claim 19, wherein the electronic system is an electric car or a mobile device.

39. The estimation device as claimed in claim 19, wherein the processing circuit comprises a timing unit for calculating the duration of the specific state.

40. The estimation device as claimed in claim 39, wherein the timing unit comprises:
a pulse generator generating an immobilizing frequency; and
a counter calculating the pulse amount of the immobilizing frequency.

41. The estimation device as claimed in claim 39, wherein the timing unit comprises:
a capacitor storing charge; and
a resistor controlling the storage speed of the capacitor.

42. The estimation device as claimed in claim 19, wherein the specific action is turning off the electronic system.

43. An electronic system having a capacity to couple a power supply, comprising:
a main device executing related functions;
a battery storing a power provided by the power supply and providing a voltage to the main device; and
an estimation device estimating a remaining capacity of the battery and comprising:
a voltage detection circuit detecting voltage of the battery; and
a processing circuit determining a first reference value according to the detected result, wherein the processing circuit executes a specific action when the duration of a specific state arrives at a preset time; and
a display device displaying the remaining capacity of the battery.

44. The electronic system as claimed in claim 43, wherein the specific action is again detecting the voltage of the battery to determine a second reference value.

45. The electronic system as claimed in claim 44, wherein the display device is changed to display the remaining capacity corresponding to the second reference value.

46. The electronic system as claimed in claim 44, wherein the processing circuit updates a full charge capacity of the battery according to the first and the second reference values.

47. The electronic system as claimed in claim 44, wherein the processing circuit compares the voltage of the battery and relational data for determining the first or the second reference value.

48. The electronic system as claimed in claim 47, wherein the relational data is a relationship between state of charge (SOC) of the battery and the voltage of the battery.

49. The electronic system as claimed in claim 43, wherein the processing circuit determines an amount of change in the remaining capacity according to a monitoring method and corrects the first reference value according to the amount of change for determining a second reference value.

50. The electronic system as claimed in claim 49, wherein the processing circuit further comprises a current detection unit to detect current of the battery.

51. The electronic system as claimed in claim 50, wherein the processing circuit utilizes an integration formula to process the current of the battery.

52. The electronic system as claimed in claim 51, wherein the processing circuit determines a full charge capacity of the battery according to the first and the second reference values and the integral result.

53. The electronic system as claimed in claim 52, wherein the processing circuit corrects the first reference value according to the full charge capacity.

54. The electronic system as claimed in claim 51, wherein the processing circuit corrects the first reference value to determine a second reference value according to the integral result.

55. The electronic system as claimed in claim 43, wherein the processing circuit finds the specific state according to a specific method.

56. The electronic system as claimed in claim 55, wherein the specific method is detecting current of the battery.

57. The electronic system as claimed in claim 43, wherein the specific state is found when the current of the battery is less than a preset value.

58. The electronic system as claimed in claim 43, wherein the processing circuit determines a full charge capacity of the battery according to a usage state of the battery.

59. The electronic system as claimed in claim 43, wherein the processing circuit determines a full charge capacity of the battery according to an amount of time for using the battery.

60. The electronic system as claimed in claim 43, wherein the processing circuit determines a full charge capacity of the battery according to a circulating amount of using the battery.

61. The electronic system as claimed in claim 43, wherein the display device displays the remaining capacity corresponding to the first reference value when the first reference value is determined by the processing circuit.

62. The electronic system as claimed in claim 43, wherein the electronic system is an electric car or a mobile device.

63. The electronic system as claimed in claim 43, wherein the processing circuit comprises a timing unit for calculating the duration of the specific state.

64. The electronic system as claimed in claim 63, wherein the timing unit comprises:
a pulse generator generating an immobilizing frequency; and
a counter calculating the pulse amount of the immobilizing frequency.

65. The electronic system as claimed in claim 63, wherein the timing unit comprises:
a capacitor storing charge; and
a resistor controlling the storing speed of capacitor.

66. The electronic system as claimed in claim 43, wherein the specific action is turning off the electronic system.
